(19) United States
(12) Patent Application Publication
(10) Pub. No.: US 2012/0087722 A1
(43) Pub. Date: Apr. 12, 2012

(54) COUPLING MECHANISM

(75) Inventors: HO-YUAN LIN, TUCHENG CITY (TW); CHING-FENG HSIEH, TAIPEI CITY (TW)

(73) Assignee: ASKEY COMPUTER CORP., TAIPEI (TW)

(21) Appl. No.: 12/957,779

(22) Filed: Dec. 1, 2010

(30) Foreign Application Priority Data
Oct. 12, 2010 (TW) 099134713

(51) Int. Cl. H05K 5/02

(52) U.S. Cl. 403/327

(57) ABSTRACT

A coupling mechanism for coupling together a first body and a second body of an electronic device includes a first engagement module and a second engagement module. The first engagement module is disposed at the first body and has an engagement groove and a first guiding slope connected thereto. The second engagement module is disposed in a receiving space of the second body and includes an engaging member and a resilient element. The engaging member has a pressing portion and an engaging portion. The pressing portion protrudes from the second body so as to be pressed. The engaging portion is slidable relative to the first guiding slope to thereby lift/lower the engaging member, and is engageable with the engagement groove to couple the first and second bodies together. The resilient element exerts a resilient force upon the engaging member according to the lifted/lowered state of the engaging member.

### CROSS-REFERENCE TO RELATED APPLICATION

This non-provisional application claims priority under 35 U.S.C. §119(a) on Patent Application No(s). 099134713 filed in Taiwan, R.O.C. on Oct. 12, 2010, the entire contents of which are hereby incorporated by reference.

### FIELD OF THE TECHNOLOGY

The present invention relates to coupling mechanisms, and more particularly, to a coupling mechanism that reinforces an electronic device and ensures ease of assembly and disassembly thereof.

### BACKGROUND

Replaceable parts and components of a conventional device are coupled to the main body of the conventional device by means of a removable coupling mechanism. Examples of the coupling mechanism are screws, rivets, and engagement structures.

Take an electronic device as an example, a common instance of a need to couple together the electronic device and a part/component thereof is coupling together a battery and the main body of the electronic device. A conventional way to do so involves placing the battery in a recess on the back of the main body of the electronic device, fixing the battery to the recess by the engagement of a tenon extending from the battery and a groove on a lateral side of the recess on the back of the main body of the electronic device, and covering the battery with a lid to protect the battery.

Nonetheless, the conventional tenon of the battery is much smaller than the battery proper, and thus the conventional tenon of the battery is not effective in coupling together the battery and the main body of the electronic device. For example, the battery is likely to separate from the main body of the electronic device as a result of an inadvertent fall of the electronic device. However, any attempt to reinforce the engagement of the tenon and the groove will require a complicate design of the engagement inevitably and, as a result, it is inconvenient to assemble, disassemble, and use the electronic device.

Furthermore, the conventional tenon lacks ease of use, because a user has to push the conventional tenon with both hands so as for the battery to be fixed to or removed from the recess of the electronic device.

Accordingly, it is imperative to provide a coupling mechanism for reinforcing an electronic device in which the coupling mechanism is disposed and ensuring ease of assembly and disassembly of the electronic device.

### SUMMARY

In view of the shortcomings of the conventional coupling mechanism, the inventor of the present invention conducted extensive researches and experiments according to the inventor's years of experience in the related industry, and finally developed a coupling mechanism as disclosed in the present invention to reinforce an electronic device in which the coupling mechanism is disposed and ensure ease of assembly and disassembly of the electronic device.

It is a primary objective of the present invention to provide a coupling mechanism comprising a guiding slope, a resilient element, an engaging member, and an engagement groove so as to reinforce an electronic device in which the coupling mechanism is disposed and ensure ease of assembly and disassembly of the electronic device.

In order to achieve the above and other objectives, the present invention provides a coupling mechanism for coupling together a first body and a second body of an electronic device, wherein the second body has therein a receiving space for receiving the first body.

The coupling mechanism of the present invention comprises a first engagement module and a second engagement module. The first engagement module is disposed at a first body of the electronic device. The first engagement module comprises a first guiding slope and an engagement groove. The first guiding slope is connected to the engagement groove. The second engagement module is disposed in a receiving space of a second body of the electronic device. The second engagement module comprises an engaging member connected to the second body and a resilient element abutting against the engaging member. The engaging member comprises a pressing portion and an engaging portion. The pressing portion protrudes out of the second body to serve a pressing purpose. The engaging portion slides relative to the first guiding slope as soon as the first body is inserted into the receiving space, so as to enable the engaging member to be lifted or lowered; meanwhile, the engaging portion is engaged with the engagement groove to couple the first body and the second body together. The resilient element exerts a resilient force upon the engaging member according to the lifted/lowered state of the engaging member.

Hence, given the first guiding slope, the resilient element, the engaging member, and the engagement groove, it is feasible for the coupling mechanism to reinforce an electronic device in which the coupling mechanism is disposed and ensure ease of assembly and disassembly of the electronic device.

The engaging portion of the engaging member further has a second guiding slope. The second guiding slope slides relative to the first guiding slope as soon as the first body is inserted into the receiving space.

The second engagement module further has a fixing base. The fixing base is disposed at the second body. The engaging member is disposed at the fixing base and slidable relative to the fixing base, and thus the engaging member can be lifted or lowered relative to the fixing base. The resilient element is disposed between the fixing base and the engaging member. The resilient element exerts a resilient force upon the engaging member according to the lifted/lowered state of the engaging member.

The engaging member further has a sliding groove. The second engagement module further comprises a positioning pin. The sliding groove is penetrable by the positioning pin, and the positioning pin is disposed at the fixing base.

### BRIEF DESCRIPTION OF THE DRAWINGS

A detailed description of further features and advantages of the present invention is given below so that a person skilled in the art can understand and implement the technical contents of the present invention and readily comprehend the objectives, features, and advantages thereof by reviewing the disclosure of the present specification and the appended claims in conjunction with the accompanying drawings, in which:

FIG. 1 is an exploded view of a preferred embodiment according to the present invention;

FIG. 2 is a perspective view of the preferred embodiment according to the present invention;

FIG. 3 is a schematic view of operation of the preferred embodiment according to the present invention;

FIG. 4 is another schematic view of operation of the preferred embodiment according to the present invention; and

FIG. 5 is a schematic view of a coupling mechanism of the preferred embodiment according to the present invention.

### DETAILED DESCRIPTION

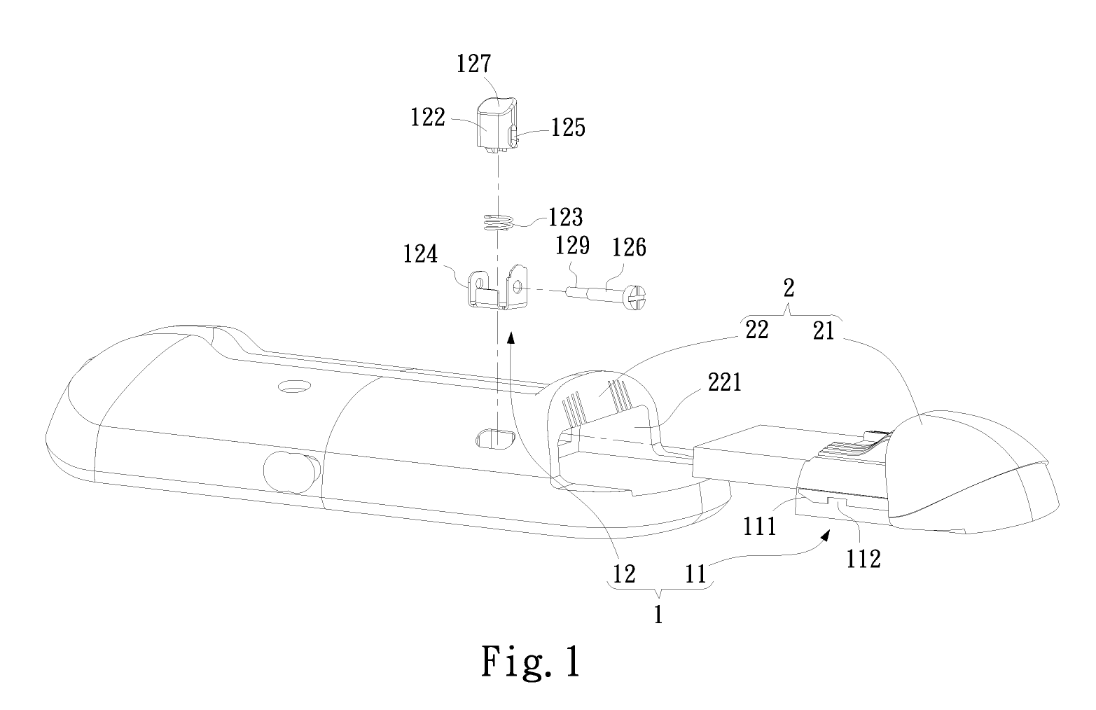

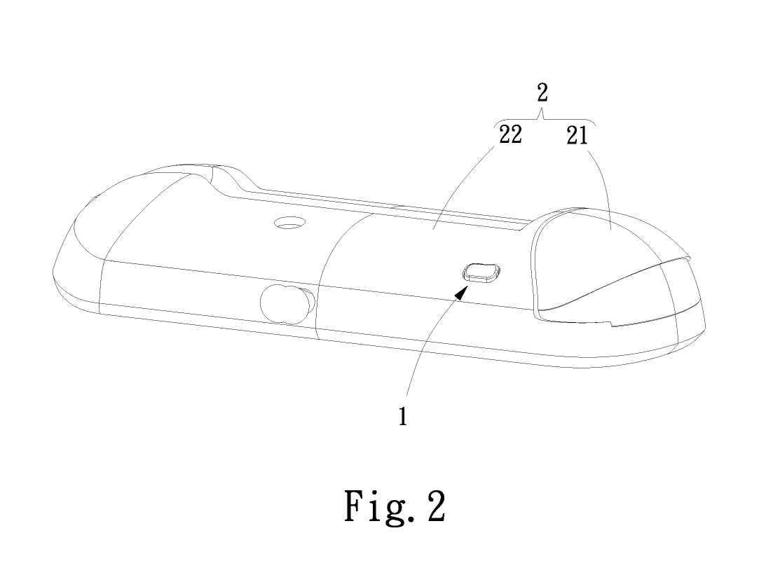

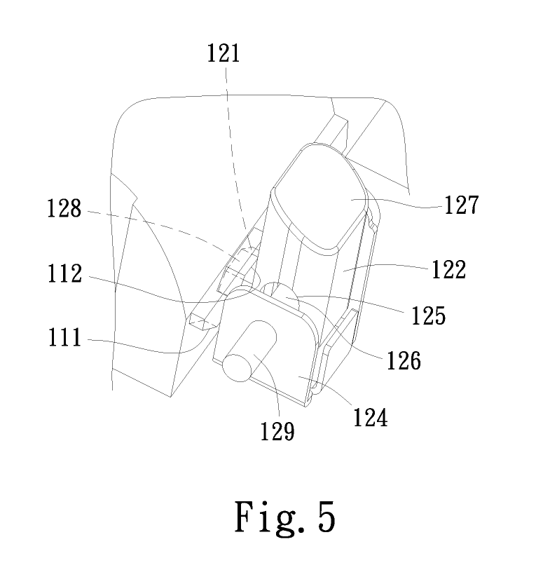

Referring to FIG. 1, FIG. 2, and FIG. 5, there are shown an exploded view and a perspective view of a preferred embodiment according to the present invention, and a schematic view of a coupling mechanism 1 of the preferred embodiment according to the present invention.

As shown in the drawings, a portable electronic device 2 (such as a handheld electronic scanner) has a first body 21 (such as a battery) and a second body 22 (such as the main body of an electronic device). The first body 21 can be coupled to the second body 22. The second body 22 has a receiving space 221 therein. The first body 21 can be received in the receiving space 221 of the second body 22. The first body 21 and the second body 22 can be coupled together by the coupling mechanism 1.

As shown in the drawings, the coupling mechanism 1 comprises a first engagement module 11 and a second engagement module 12. The first engagement module 11 is disposed at the first body 21 of the portable electronic device 2. The first engagement module 11 has a first guiding slope 111 and an engagement groove 112. The first guiding slope 111 is connected to the engagement groove 112.

The second engagement module 12 is disposed in the receiving space 221 of the second body 22 of the portable electronic device 2. The second engagement module 12 comprises an engaging member 122 connected to the second body 22 and a resilient element 123 abutting against the engaging member 122. The engaging member 122 comprises a pressing portion 127 and an engaging portion 128. The pressing portion 127 protrudes out of the second body 22 to serve a pressing purpose. The engaging portion 128 is slidable relative to the first guiding slope 111 as soon as the first body 21 is inserted into the receiving space 221 of the second body 22, so as to enable the engaging member 122 to be lifted or lowered; meanwhile, the engaging portion 128 is engageable with the engagement groove 112 to couple the first body 21 and the second body 22 together. The resilient element 123 exerts a resilient force upon the engaging member 122 according to the lifted/lowered state of the engaging member 122.

In this embodiment, the engaging portion 128 further has a second guiding slope 121. The second guiding slope 121 is slidable relative to the first guiding slope 111 as soon as the first body 21 is inserted into the receiving space 221 of the second body 22.

In this embodiment, the second engagement module 12 further comprises a fixing base 124. The fixing base 124 is U-shaped and is disposed at the second body 22. The engaging member 122 is disposed at the fixing base and slidable relative to the fixing base 124, and thus the engaging member 122 can be lifted and lowered relative to the fixing base 124. The resilient element 123 is disposed between the fixing base 124 and the engaging member 122. The resilient element 123 exerts a resilient force upon the engaging member 122 according to the lifted/lowered state of the engaging member 122. In this embodiment, the resilient element 123 is a spring.

To enable the engaging member 122 to be slidable relative to the fixing base 124 and capable of bringing about a position-limiting effect by effectuating a vertical displacement when being lifted or lowered relative to the fixing base 124, the coupling mechanism 1 of the present invention is characterized in that: the engaging member 122 further has a sliding groove 125, and the second engagement module 12 further comprises a positioning pin 126. The sliding groove 125 is penetrated by the positioning pin 126. The positioning pin 126 is disposed at the fixing base 124. In this embodiment, threads are disposed on an end portion 129 of the positioning pin 126 to assist the positioning pin 126 in being disposed at the fixing base 124. Also, the middle of the positioning pin 126 is not threaded but smooth to allow the engaging member 122 to be lifted or lowered relative to the positioning pin 126.

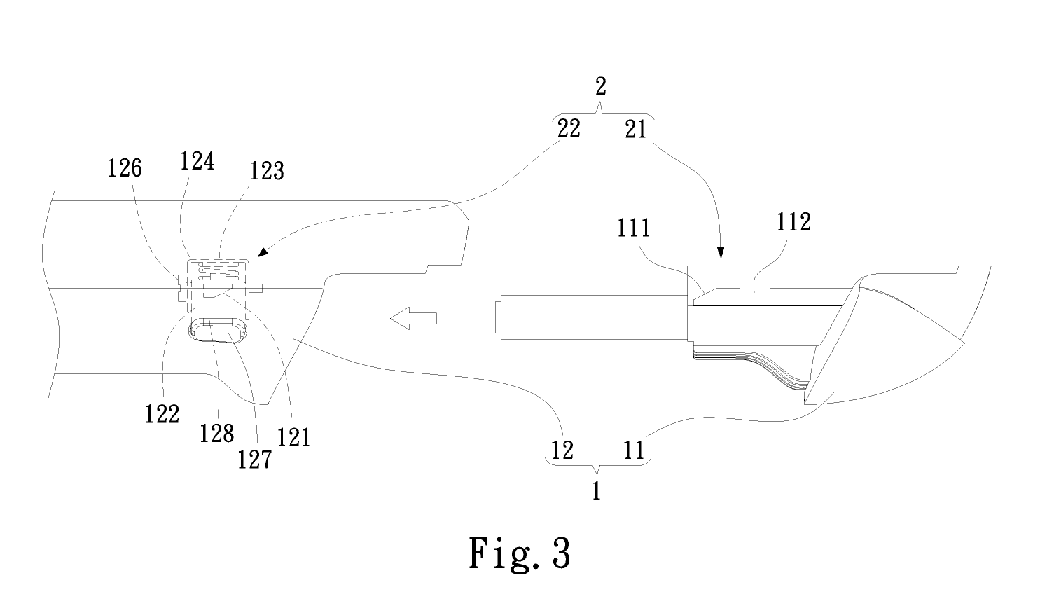

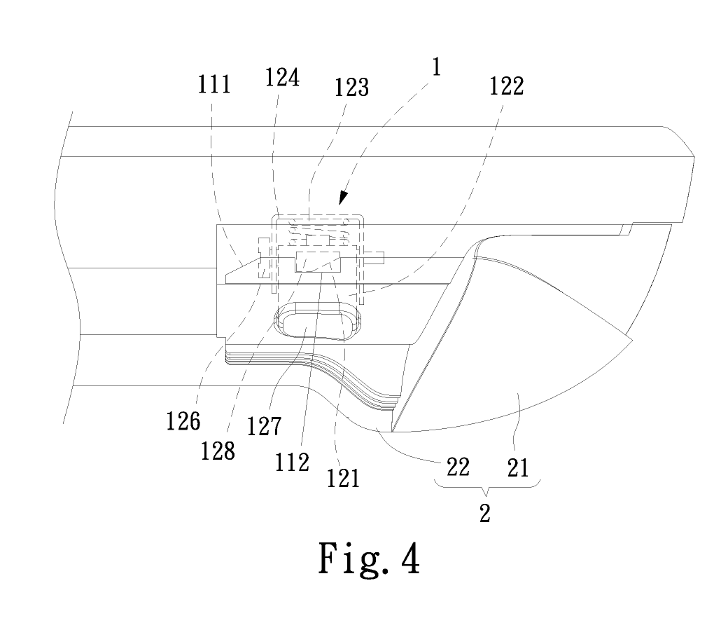

Referring to FIG. 3 and FIG. 4, there are shown schematic views of operation of the preferred embodiment according to the present invention.

As shown in FIG. 1 through FIG. 5, to enable the first body 21 to be coupled to the second body 22, a user slides the first body 21 into the receiving space 221 of the second body 22; meanwhile, the first guiding slope 111 of the first engagement module 11 of the first body 21 comes into contact with the second guiding slope 121 in the receiving space 221 of the second body 22. Afterwards, the first guiding slope 111 and the second guiding slope 121 are slidable toward each other. Due to the design of the guiding slope, the first guiding slope 111 abuts against the engaging member 122 (upon which a resilient force is exerted by the resilient element 123) to thereby lift or lower the engaging member 122. The engaging portion 128 will be engaged with the engagement groove 112 under the resilient force exerted upon the engaging member 122 by the resilient element 123, provided that the first body 21 continues to slide into the second body 22 until the engaging portion 128 is aligned with the engagement groove 112.

The first body 21 and the second body 22 are readily slidable toward each other because of the first guiding slope 111 and the second guiding slope 121. It is easy for the first body 21 to slide into the receiving space 221 of the second body 22 to thereby allow the engaging portion 128 to be engaged with the engagement groove 112. The resilient force of the resilient element 123 adds to the degree of engagement between the engaging portion 128 and the engagement groove 112. As a result, the first body 21 and the second body 22 are firmly coupled together.

To withdraw the first body 21 from the second body 22, the user presses the pressing portion 127 of the engaging member 122 to enable the engaging portion 128 of the engaging member 122 to separate from the engagement groove 112. The first body 21 bounces off the second body 22 as soon as the first guiding slope 111 and the second guiding slope 121 begin to abut against each other under the resilient force exerted upon the engaging member 122 by the resilient element 123.

With the sliding groove 125 being penetrated by the positioning pin 126, the engaging member 122 demonstrates a vertical displacement-dependent position-limiting effect in the course of the lifting or lowering of the engaging member 122 relative to the fixing base 124 under the resilient force of the resilient element 123.

The coupling mechanism 1 of the present invention demonstrates ease of use, because users can easily couple together or separate the first body 21 and the second body 22 single-handedly, that is, using only one hand.

Accordingly, given the first guiding slope 111, the second guiding slope 121, the resilient element 123, the engaging member 122, and the engagement groove 112, it is feasible to reinforce an electronic device in which the coupling mechanism 1 is disposed and ensure ease of assembly and disassembly of the electronic device.

Hence, the present invention meets the three requirements of patentability, namely novelty, non-obviousness, and industrial applicability. Regarding novelty and non-obviousness, the present invention discloses a coupling mechanism for reinforcing an electronic device in which the coupling mechanism is disposed and ensuring ease of assembly and disassembly of the electronic device by means of the constituent components of the coupling mechanism, such as a guiding slope, a resilient element, an engaging member, and an engagement groove. Regarding industrial applicability, products derived from the present invention meet market demands fully.

The foregoing embodiments are provided to illustrate and disclose the technical features of the present invention so as to enable persons skilled in the art to understand the disclosure of the present invention and implement the present invention accordingly, and are not intended to be restrictive of the scope of the present invention. Hence, all equivalent modifications and variations made to the foregoing embodiments without departing from the spirit and principles in the disclosure of the present invention should fall within the scope of the present invention as set forth in the appended claims.

What is claimed is:

1. A coupling mechanism for coupling together a first body and a second body of an electronic device, the second body having therein a receiving space for receiving the first body, the coupling mechanism comprising:
a first engagement module disposed at the first body, the first engagement module comprising a first guiding slope and an engagement groove, the first guiding slope being connected to the engagement groove; and
a second engagement module disposed in the receiving space of the second body, the second engagement module comprising an engaging member connected to the second body and a resilient element abutting against the engaging member, the engaging member comprising a pressing portion and an engaging portion, the pressing portion protruding out of the second body to serve a pressing purpose, the engaging portion being slidable relative to the first guiding slope as soon as the first body is inserted into the receiving space, so as to enable the engaging member to be lifted or lowered, and the engaging portion being engageable with the engagement groove to couple the first body and the second body together, wherein the resilient element exerts a resilient force upon the engaging member according to a lifted/lowered state of the engaging member.

2. The coupling mechanism of claim 1, wherein the engaging portion has a second guiding slope slidable relative to the first guiding slope as soon as the first body is inserted into the receiving space.

3. The coupling mechanism of claim 1, wherein the second engagement module further has a fixing base disposed at the second body, thereby allowing the engaging member to be slided and thereby lifted and lowered relative to the fixing base, wherein the resilient element is disposed between the fixing base and the engaging member and configured to exert a resilient force upon the engaging member according to the lifted/lowered state of the engaging member.

4. The coupling mechanism of claim 3, wherein the engaging member further has a sliding groove, and the second engagement module further comprises a positioning pin, the sliding groove being penetrable by the positioning pin, and the positioning pin being disposed at the fixing base.

5. The coupling mechanism of claim 4, wherein the positioning pin having an end portion provided with threads for assisting the positioning pin in being disposed at the fixing base.

6. The coupling mechanism of claim 3, wherein the fixing base is U-shaped.

7. The coupling mechanism of claim 1, wherein the resilient element is a spring.
